(19) United States
(12) Patent Application Publication
(10) Pub. No.: US 2026/0161204 A1
(43) Pub. Date: Jun. 11, 2026

(54) INTEGRATED LIQUID COOLING IN A CARD-BASED COMPUTING DEVICE

(71) Applicant: NVIDIA CORPORATION, Santa Clara, CA (US)

(72) Inventors: Xiangyang AN, Shenzhen City (CN); Zhenguang HUANG, Shenzhen City (CN); Zhi TAN, Shenzhen City (CN); Zhiqiang YU, Shenzhen City (CN); Dongmei NIU, Shenzhen City (CN); Qiang CHEN, Shenzhen, Guangdong (CN)

(21) Appl. No.: 18/706,715

(22) PCT Filed: Apr. 18, 2024
(86) PCT No.: PCT/CN2024/088689

§ 371 Date: May 1, 2024

(51) Int. Cl. G06F 1/20; H05K 7/20

(52) U.S. Cl. CPC G06F 1/20; H05K 7/20154; H05K 7/20263; H05K 7/20272; H05K 7/20254

(57) ABSTRACT

According to various embodiments, a processing subsystem includes a housing; a printed circuit board (PCB) disposed within the housing; an integrated circuit package that has a first side and a second side that is opposite to the first side, wherein the first side of the integrated circuit package is mounted on the PCB; and a liquid-based cooling system. The liquid-based cooling system is disposed within the housing and includes: at least one radiator element; a pump that is fluidly coupled to the radiator element; and at least one fan that directs cooling air across the radiator element.

### BACKGROUND

### Field of the Various Embodiments

The various embodiments relate generally to computer architecture and electronics and, more specifically, to integrated liquid cooling in a card-based computing device.

### Description of the Related Art

Many types of computers are designed to incorporate one or more expansion cards that provide the computer with additional capabilities, such as enhanced video or gaming performance, accelerated video capture, the ability to connect to a network, and/or the ability to connect to a musical instrument, to name a few. An expansion card, which also is referred to as an adapter card, an add-on card, or an expansion board, is a card-based processing subsystem that typically includes a printed circuit board (PCB) that is adapted to connect to an expansion slot on the motherboard of a given computer system.

As the power consumption of modern graphics cards and other card-based processing subsystems continues to increase, removal of heat generated by these types of subsystems becomes a greater challenge. In an effort to remove sufficient heat from computer systems that incorporate card-based processing subsystems, forced-air fans have been integrated into some types of card-based processing subsystems. In such implementations, one or more fans direct air across a heat sink that is coupled to a high-power integrated circuit (IC) of the card-based processing subsystem, which enables the heat sink to remove significantly more of the heat produced by the IC than can be removed by designs that rely on free convection of air. To increase heat removal from high-power ICs further, some card-based processing subsystems also include multi-phase thermal solutions, such as heat pipes and/or vapor chambers. Unfortunately, even the heat-carrying capacity of heat sinks augmented with forced-air fans and multi-phase thermal solutions can be outstripped by certain very high-performance ICs, such as the graphics processing units (GPUs) of modern graphics cards. This is true even when high fan speeds are employed, which can generate significant and unwanted noise.

To enable adequate cooling of the highest-performance ICs, liquid-based cooling systems have been developed for card-based processing subsystems. A conventional liquid-based cooling system usually includes a pump that forces an IC-cooling liquid through a heat-exchanger, such as a radiator, at a high flow rate. The heat-exchanger typically is cooled using one or more forced-air fans. As a general matter, liquid-based cooling systems tend to have much greater cooling capacities than multi-phase thermal solutions, such as the heat pipes and vapor chambers mentioned above.

Some types of liquid-based cooling systems include an external radiator element that is mounted within a computer chassis separately from the card-based processing subsystem being cooled. The card-based processing subsystem, which is mounted on the computer motherboard, is fluidly coupled to the external radiator element via cooling lines routed within the computer chassis. One drawback of using an external radiator element in this fashion is that the computer chassis usually has to be specifically designed to support the external radiator element. For example, in many instances, a computer chassis has no mounting location for an external radiator element or has a mounting location already occupied by an existing external radiator element. Another drawback of using a liquid-based cooling system that includes an external radiator element is that the overall installation become more complex relative to the “plug-and-play” installation for a typical card-based processing subsystem. Instead of simply plugging a PCB into a card-connector on the computer motherboard, the user also has to rout the cooling lines correctly, mount the external radiator element, and connect the external radiator element to a power source.

Other types of liquid-based cooling systems are incorporated into a computer chassis at the factory, and the user then has to connect the cooling system to a card-based processing subsystem via one or more cooling lines. One drawback of using these types of liquid-based cooling systems is that a card-based processing subsystem has to be specifically designed to be connected to such a cooling system. For example, the card-based processing subsystem has to have suitably configured liquid inlet and outlet connections that are compatible with the liquid-based cooling system that is incorporated into the computer chassis. Another drawback is that the liquid-based cooling system in the computer chassis may not have sufficient capacity or sufficient cooling lines to properly cool the card-based processing subsystem. A further drawback is that installation of the card-based processing subsystem is more involved relative to the “plug-and-play” installation for a typical card-based processing subsystem. Yet another drawback is that oftentimes there is a higher risk of leakage from the cooling system, given that the liquid connections are made by the user and are not sealed and tested at the factory.

As the foregoing illustrates, what is needed in the art are more effective techniques for cooling card-based processing subsystems in computer systems.

### SUMMARY

According to various embodiments, a processing subsystem includes a housing; a printed circuit board (PCB) disposed within the housing; an integrated circuit package that has a first side and a second side that is opposite to the first side, wherein the first side of the integrated circuit package is mounted on the PCB; and a liquid-based cooling system. The liquid-based cooling system is disposed within the housing and includes: at least one radiator element; a pump that is fluidly coupled to the radiator element; and at least one fan that directs cooling air across the radiator element

At least one technical advantage of the disclosed design relative to the prior art is that the disclosed design provides a heat-removing capacity to a card-based processing subsystem that is commensurate with the heat removal capacity of a liquid-based cooling system. Further, the card-based processing system in the disclosed design can maintain a form factor that is commensurate with the form-factor of a card-based processing subsystem that only includes a fan-based or multi-phase thermal solution. Thus, the disclosed design enables high cooling capacity with relatively simple installation. Another technical advantage is that, due to the high cooling capacity associated with the disclosed design, lower fan speeds can be employed in many instances, which can substantially reduce fan noise. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a computer system configured to implement one or more aspects of the various embodiments.

FIG. 2 is a more detailed illustration of the computer system of FIG. 1, according to various embodiments.

FIG. 3 is a conceptual block diagram of the card-based processing subsystem of FIG. 2, according to various embodiments.

FIGS. 4A-4C are more detailed illustrations of a card-based processing subsystem, according to various other embodiments.

FIG. 5 illustrates a portion of a motherboard that is adapted to receive a card-based processing subsystem, according to various embodiments.

FIG. 6A is a conceptual perspective view of a card-based processing subsystem, according to various embodiments.

FIG. 6B is a side view of the card-based processing subsystem of FIG. 6A with portions of a housing omitted for clarity, according to various embodiments.

FIG. 7 is a conceptual block diagram of the card-based processing subsystem of FIGS. 6A and 6B, according to various embodiments.

FIG. 8 is a conceptual block diagram of the card-based processing subsystem of FIGS. 6A and 6B, according to various other embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

### System Overview

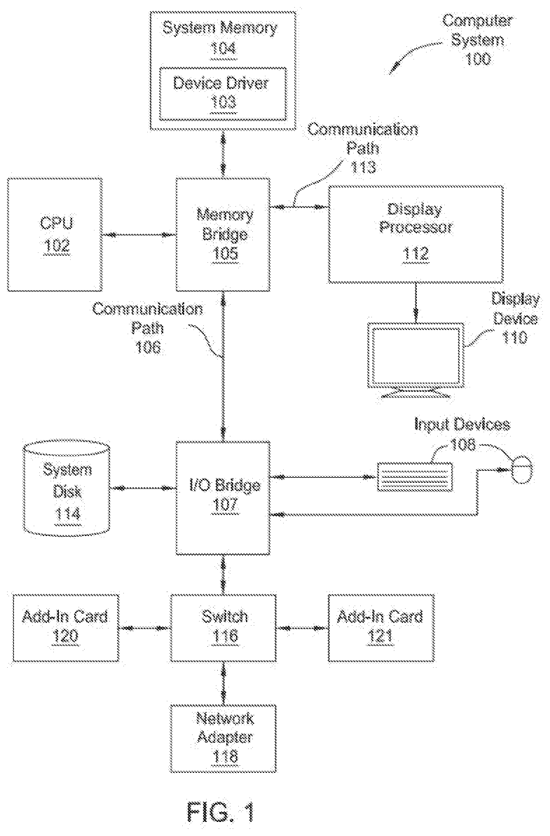

FIG. 1 is a conceptual illustration of a computer system 100 configured to implement one or more aspects of the various embodiments. As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. I/O bridge 107, which may be, e.g., a Southbridge chip, receives user input from one or more user input devices 108 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link); in one embodiment display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e.g., a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, a graphical user interface is displayed to one or more users via display device 110, and the one or more users can input data into and receive visual output from the graphical user interface.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121. Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 is configured as a processing subsystem that incorporates circuitry optimized for graphics and video processing, including, for example, video output circuitry, and constitutes a graphics processing unit (GPU). In another embodiment, display processor 112 is configured as a processing subsystem that incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processing device configured to process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 102, display processor 112, or one or more other processing devices or any combination of these different processors. In other contemplated embodiments, system 100 may or may not include other elements shown in FIG. 1.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

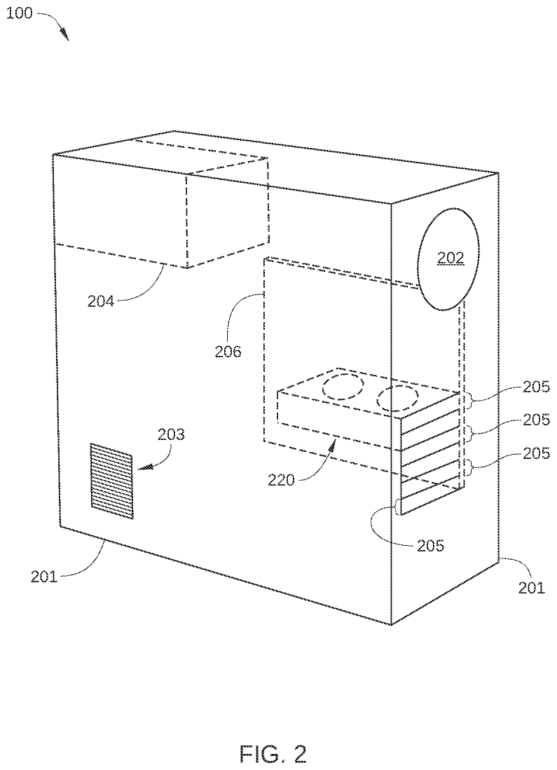

FIG. 2 is a more detailed illustration of computer system 100, according to various embodiment. As shown, computer system 100 includes a chassis 201 (also referred to as a “case” or “housing”) with one or more system cooling fans 202 mounted thereon and one or more cooling inlets 203 formed therein. Cooling fans 202 are configured to draw cooling air into chassis 201, for example via cooling inlets 203, in order to remove heat generated by various electronic components of computer system 100. Computer system 100 further includes a power supply 204 mounted within chassis 201, a plurality of chassis expansion slots 205 that are typically located on a rear surface of chassis 201, and a motherboard 206 disposed within chassis 201.

Computer system 100 further includes various external connections (omitted for clarity) mounted or disposed on a rear and/or front surface of chassis 201, such as a power connection, Universal Serial Bus (USB) connections, an audio input jack, an audio output jack, one or more video output connections, and/or other connections. In some embodiments, one or more of such external connections are associated with motherboard 206 and/or one or more expansion cards that are coupled to motherboard 206 and installed in a chassis expansion slot 205, such as a card-based processing subsystem 220.

In the embodiment illustrated in FIG. 2, motherboard 206 is configured with a central processing unit (CPU) and one or more card edge connectors, such as peripheral component interconnect express (PCIe) slots, that are each positioned to correspond to a different chassis expansion slot 205. For clarity, the CPU and card edge connectors of motherboard 206 are omitted in FIG. 2. Generally, computer system 100 is configured with one or more expansion cards or other card-based processing subsystems that are each mounted in a different chassis expansion slot 205 and communicatively coupled to motherboard 206 via a corresponding card edge connector. Examples of such card-based processing subsystems include card-based processing subsystems 220, such as wireless adapters, sound cards, graphics cards, network adapter 118, add-in cards 120, 121, or display processor 112 of FIG. 1, and/or the like. In the embodiment illustrated in FIG. 2, a single card-based processing subsystem 220 is coupled to motherboard 206, but in other embodiments, a plurality of card-based processing subsystems 220 may be coupled to motherboard 206.

In some embodiments, computer system 100 further includes one or more peripheral devices (not shown) that are communicatively coupled to motherboard 206 and/or a particular expansion card coupled to motherboard 206. For example, in some embodiments, computer system 100 includes one or more of a keyboard, mouse, joystick, digitizer tablet, touch pad, touch screen, display device, external hard drive, still or video cameras, motion sensors, microphones, and/or the like.

In the embodiment illustrated in FIG. 2, computer system 100 is depicted as a tower-configured desktop computer system. In other embodiments, computer system 100 can have any configuration that can include a card-based processing subsystem, such as a tower server computer system, a blade server computer system, a rack server computer system, a laptop computer, and the like.

### Card-Based Processing Subsystem with Integrated Liquid Cooling

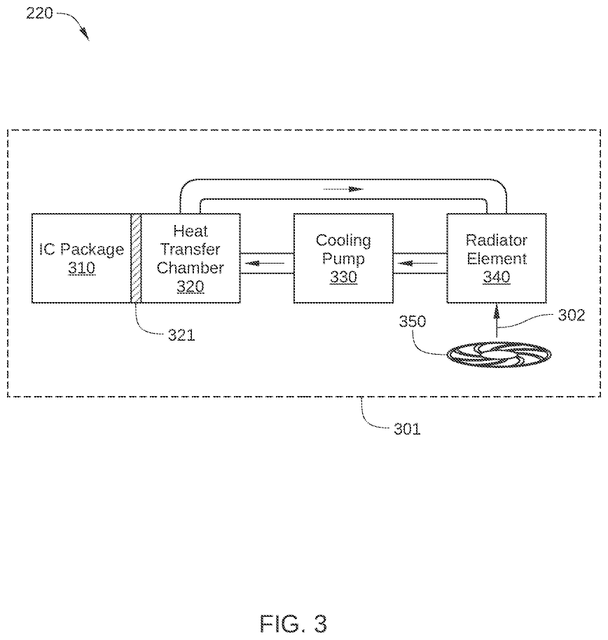

FIG. 3 is a conceptual block diagram of card-based processing subsystem 220, according to various embodiments. As shown, card-based processing subsystem 220 includes an integrated circuit (IC) package 310, a heat transfer chamber 320, a cooling pump 330, a radiator element 340, and a cooling fan 350, all disposed within a housing 301. In some embodiments, housing 301 has a form factor and electrical and mechanical connections (not shown) that enable the installation of card-based processing subsystem 220 onto a motherboard of a computer, such as motherboard 206 in FIG. 2.

IC package 310 includes one or more high-power ICs, chips, and/or processing cores, which may be limited in performance based on operating temperature. As a result, the performance of the one or more high-power ICs, chips, and/or processing cores included in IC package 310 is generally increased when cooling is applied to IC package 310 during operation via heat transfer chamber 320. For example, in embodiments in which card-based processing subsystem 220 is configured as a graphics card, IC package 310 includes a graphics processing unit (GPU) and, in some instances, one or more high-bandwidth memory chips or other memory chips.

Heat transfer chamber 320 is chamber that contains a cooling liquid and is coupled to at least one side of IC package 310 for the removal of heat from IC package 310. In some embodiments, heat transfer chamber 320 includes a cold plate 321 that can include skived fins or other cooling fins for enhanced heat transfer from IC package 310 into heat transfer chamber 320. As shown, heat transfer chamber 320 is fluidly coupled to cooling pump 330 and radiator element 340.

Cooling pump 330 is fluidly coupled to heat transfer chamber 320 and radiator element 340 and causes the flow of a cooling liquid therebetween. The cooling liquid can be any liquid suitable for a cooling application, such as water, an alcohol solution, and the like. In the embodiment illustrated in FIG. 3, cooling pump 330 receives cooling liquid from radiator element 340 and forces the received cooling liquid into heat transfer chamber 320. In other embodiments described below, other flow configurations for the cooling liquid are contemplated.

Radiator element 340 is a liquid-to-air heat exchanger, and typically includes a plurality of liquid-containing channels (not shown) for distributing cooling liquid received from heat transfer chamber 320. In some embodiments, external cooling fins are attached to some or all of the liquid-containing channels to increase heat transfer from the liquid-containing channels to cooling air from cooling fan 350. Cooling fan 350 directs cooling air 302 across radiator element 340.

In operation, cooling pump 330 circulates the cooling liquid between heat transfer chamber 320 and radiator element 340, which is then cooled by cooling air 302. Thus, IC package 310 is cooled by cooling liquid passing through heat transfer chamber 320 and the cooling liquid is cooled by cooling air 302. The liquid cooling system for card-based processing subsystem 220 is integrated into card-based processing subsystem 220, and therefore is disposed within housing 301. As a result, card-based processing subsystem 220 has the same form-factor as a conventional card-based processing subsystem. Further, a user is not required to route and connect cooling lines within the chassis of a computer when installing card-based processing subsystem 220. Thus, card-based processing subsystem 220 is as easily installed onto a computer motherboard as a conventional card-based processing subsystem 220.

### Single Radiator Implementation

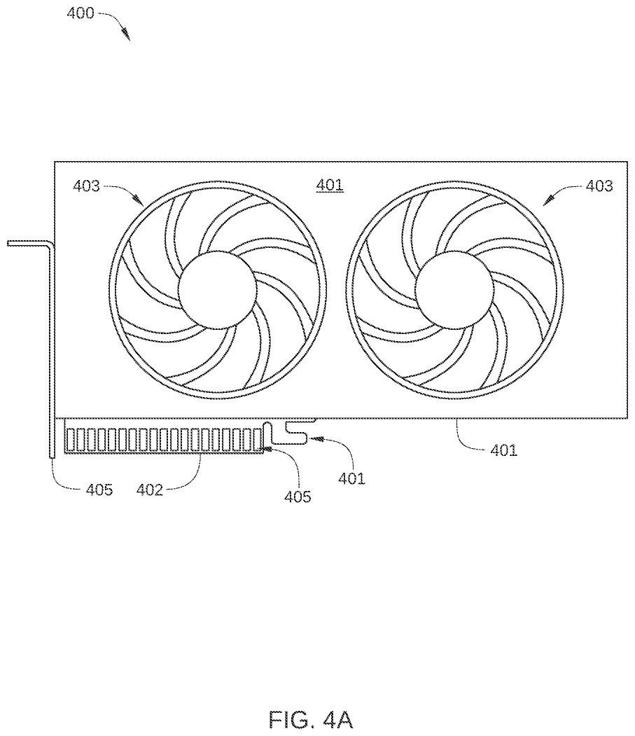

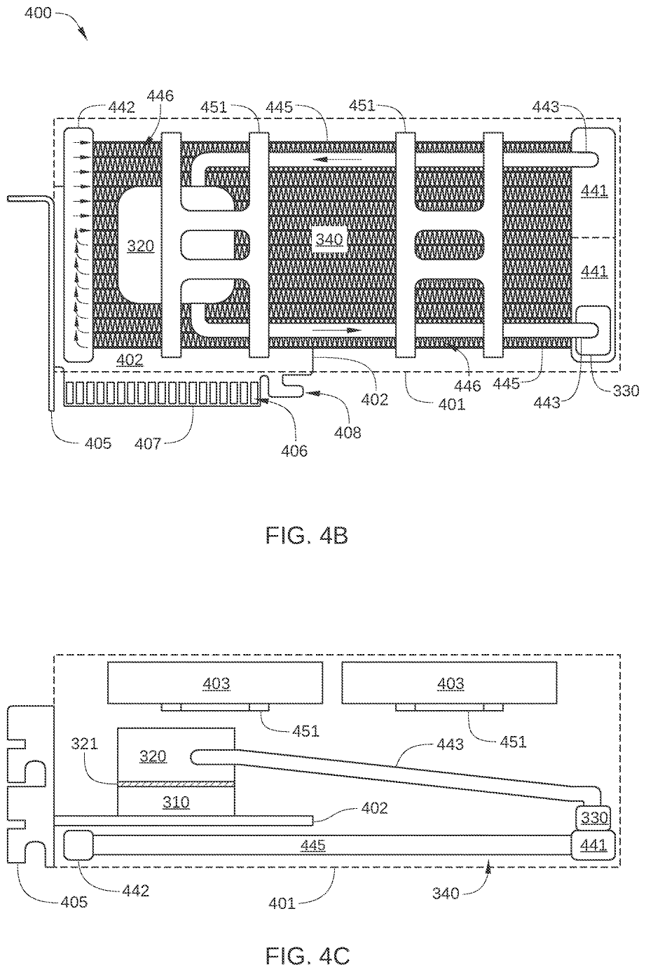

FIGS. 4A-4C are more detailed illustrations of a card-based processing subsystem 400, according to various other embodiments. FIG. 4A is a plan view of card-based processing subsystem 400, FIG. 4B is a plan view of card-based processing subsystem 400 with housing 401 and cooling fans 403 omitted for clarity, and FIG. 4C is a side view of card-based processing subsystem 400 with housing 401 omitted for clarity. As shown, card-based processing subsystem 400 includes IC package 310, heat transfer chamber 320, cooling pump 330, radiator element 340, a printed circuit board (PCB) 402, a first cooling manifold 441, a second cooling manifold 442, and cooling lines 443 all disposed within housing 401. Card-based processing subsystem 400 further includes cooling fans 403 and a backplate bracket 405 that is coupled to PCB 402.

In the embodiment illustrated in FIGS. 4A-4C , IC package 310 is coupled to PCB 402 via a first side of IC package 310 and is coupled to heat transfer chamber 320 via a second side of IC package 310. In some embodiments, the second side is opposite to the first side, as shown. In some embodiments, heat transfer chamber 320 is coupled to IC package 310 by cold plate 321.

Radiator element 340 includes a plurality of liquid-containing channels 445 for distributing cooling liquid received from heat transfer chamber 320. In some embodiments, external cooling fins 446 are attached to some or all of liquid-containing channels 445, thereby increasing heat transfer from liquid-containing channels 445 to cooling air from cooling fans 403. In the embodiment illustrated in FIG. 4A-4C , liquid-containing channels 445 of radiator element 340 are fluidly coupled to first cooling manifold 441 and second cooling manifold 442, so that cooling liquid flowing from heat transfer chamber 320 can circulate through cooling pump 330 and radiator element 340 and then back to heat transfer chamber 320. In some embodiments, first cooling manifold 441 includes two separate chambers, where one chamber receives cooling liquid from cooling pump 330 and the other chamber receives cooling liquid from the portion off liquid containing channels 445 that are directly coupled to the chamber. Thus, in such embodiments, cooling liquid flows away from first cooling manifold 441 in the liquid-containing channels 445 that are directly coupled to one chamber and toward first cooling manifold 441 in the liquid-containing channels 445 that are directly coupled to the other chamber. In other embodiments, any other suitable circulation scheme for cooling liquid can be employed between heat transfer chamber 320, cooling pump 330, and the liquid-containing channels of radiator element 340.

Cooling fans 403 can be any electrically powered fans suitable for use in a card-based processing subsystem. In the embodiment illustrated in FIGS. 4A-4C , cooling fans 403 are mounted at or near a surface of housing 401. In the embodiment illustrated in FIGS. 4A-4C , card-based processing subsystem 400 includes two cooling fans 403 for directing cooling air through radiator element 340 and in the same direction. In other embodiments, card-based processing subsystem 400 includes more than two cooling fans 403 or fewer than two cooling fans 403. Additionally or alternatively, in some embodiments, cooling fans 403 are positioned within card-based processing subsystem 400 by fan supports 451. Alternatively or additionally, cooling fans 403 can be coupled to housing 401.

PCB 402 is configured to communicatively couple card-based processing subsystem 400 to a card edge connector, such as a PCIe slot included on motherboard 206 of computer system 100, as shown in FIG. 2. To that end, PCB 402 includes a plurality of edge connector pins 406 formed on an edge 407 of PCB 402. In the embodiment illustrated in FIGS. 4A-4C , IC package 310 is mounted on PCB 402 and communicatively coupled to edge connector pins 406 by any technically feasible electrical connection known in the art, including a ball-grid array (BGA), a pin-grid array (PGA), wire bonding, electrical traces, vias, and/or the like. In some embodiments, various other ICs and/or electronic devices (not shown) are also mounted on PCB 402. In such embodiments, such ICs and/or electronic devices may be communicatively coupled to edge connector pins 406 and/or each other by any technically feasible electrical connection known in the art.

In some embodiments, PCB 402 enables card-based processing subsystem 400 to be assembled as part of a server machine, desktop computer, and the like. For example, PCB 402 can be configured for insertion into a suitable interface or slot of a backplane, a peripheral component interconnect express (PCIe) slot of a motherboard, and/or the like. In such embodiments, PCB 402 may include one or more mechanical connection features 408 for connection to a computer motherboard via a card edge connector of the motherboard. In some embodiments, PCB 402 includes a laminate substrate and is composed of a stack of insulative layers or laminates that are built up on the top and bottom surfaces of a core layer. The laminate substrate of PCB 402 can include any materials suitable for use in a PCB, including a phenolic paper substrate (e.g., FR-2, an epoxy paper substrate (e.g., CEM-1 and/or FR-3), an epoxy fiberglass board (e.g., FR-4, FR-5, G-10, and/or G-11), a non-woven glass fiber polyester substrate (e.g., FR-6), a PI polyacrylamide resin base material, and/or the like.

Generally, to enable card-based processing subsystem 400 to be assembled as part of a server machine, desktop computer, or the like, PCB 402 is coupled to backplate bracket 405. Backplate bracket 405 couples or mechanically interfaces card-based processing subsystem 400 to a surface of a chassis of a computing device. In the embodiment illustrated in FIGS. 4A-4C , backplate bracket 405 and card-based processing subsystem 400 are configured to have a width of a two chassis expansion slots 205 (shown in FIG. 2), and therefore backplate bracket 405 has a width of about 40 mm. In other embodiments, card-based processing subsystem 400 can be configured to occupy a region proximate motherboard 206 (shown in FIG. 2) that corresponds to one, three, or four chassis expansion slots 205. In such embodiments, backplate bracket 405 can have a width of about 20 mm, 60 mm, or 80 mm, respectively.

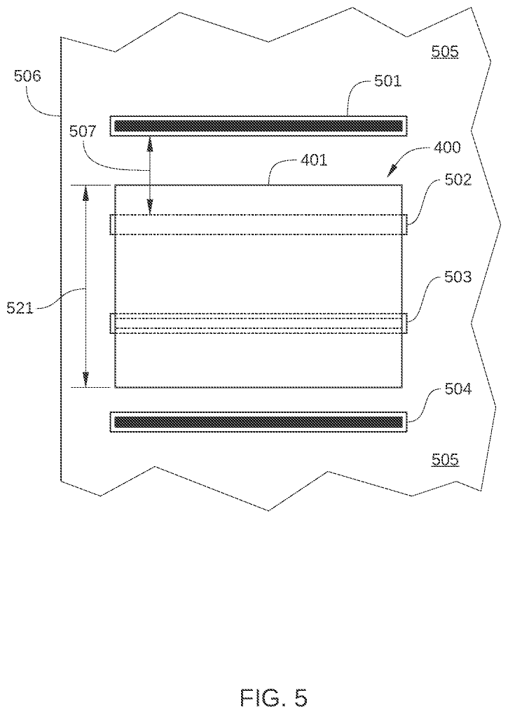

In some embodiments, housing 401 has a form factor and electrical and mechanical connections (e.g., edge connector pins 406, mechanical connection features 408, and backplate bracket 405) that enable the installation of card-based processing subsystem 400 onto a motherboard of a computer, such as motherboard 206 in FIG. 2. In such embodiments, housing 401 has a form factor that occupies a region corresponding to an integral number of expansion slots on the motherboard. One such embodiment is described below in conjunction with FIG. 5.

FIG. 5 illustrates a portion of a motherboard 505 that is adapted to receive a card-based processing subsystem, according to various embodiments. Motherboard 505 can be disposed within, for example, a chassis of the computer system 100 of FIGS. 1 and 2. As shown, motherboard 505 includes multiple expansion card slots 501-504, such as PCIe slots, which are disposed proximate a panel 506 of a computer system chassis. Generally, expansion card slots 501-504 are separated by a distance 507 that can limit a width of card-based processing subsystems installed on motherboard 505.

Also shown in FIG. 5 is card-based processing subsystem 400 installed thereon, according to various embodiments. In the embodiment illustrated in FIG. 5, card-based processing subsystem 400 has a width 521 that prevents the use of an adjacent PCIe slot. Thus, in the embodiment illustrated in FIG. 5, card-based processing subsystem 400 is installed in PCIe slot 503, but also blocks PCIe slot 502. However, PCIe slot 501 and PCIe slot 504 are still available for the installation of other card-based processing subsystems. In the embodiment illustrated in FIG. 5, card-based processing subsystem 400 utilizes space adjacent to motherboard 505 for containing a liquid cooling system that includes heat transfer chamber 320, radiator element 340, cooling pump 330, and cooling fans 403. As described herein, the liquid cooling system disposed within housing 401 can substantially improve heat transfer from IC package 310 without relying on cooling system elements disposed outside of card-based processing subsystem 400.

### Multiple Radiator Implementation

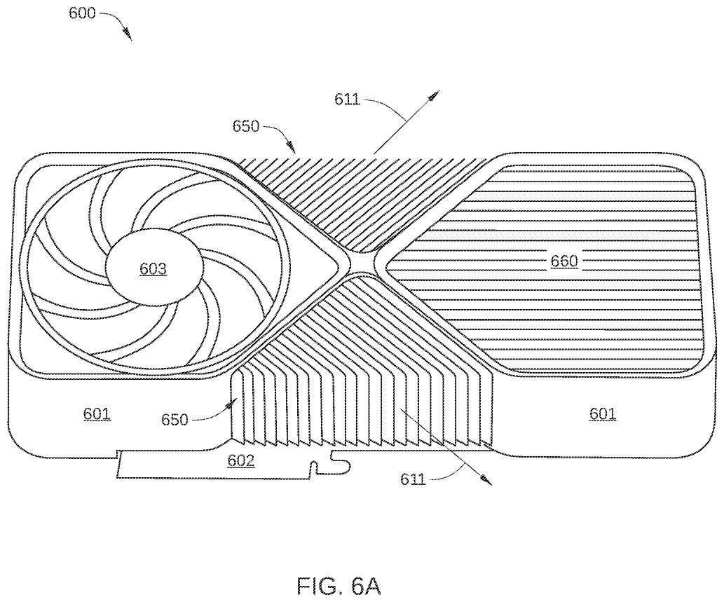

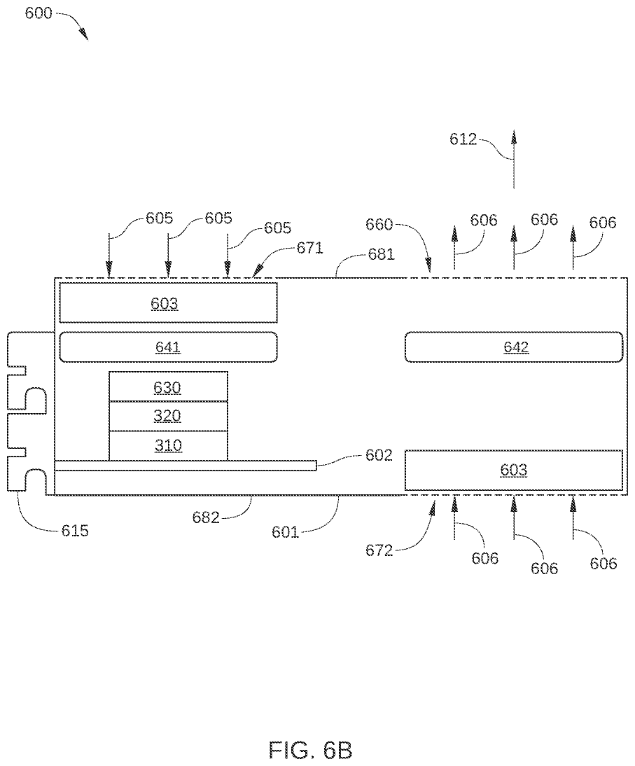

In the embodiments described above, a card-based processing subsystem includes a single radiator element. In other embodiments, a card-based processing subsystem includes multiple radiator elements. One such embodiment is described below in conjunction with FIGS. 6A and 6B.

FIG. 6A is a conceptual perspective view of card-based processing subsystem 600, according to various embodiments, and FIG. 6B is a side view of card-based processing subsystem 600 with portions of housing 601 omitted for clarity, according to various embodiments. As shown, card-based processing subsystem 600 is similar to card-based processing subsystem 400 of FIGS. 4A-4C , and includes IC package 310, heat transfer chamber 320, a cooling pump 630, a PCB 602, and cooling fans 603, all disposed within housing 601. Card-based processing subsystem 600 further includes a backplate bracket 615 that is coupled to PCB 602. In contrast to card-based processing subsystem 400, card-based processing subsystem 600 includes multiple radiator elements: a first radiator element 641 and a second radiator element 642. Card-based processing subsystem 600 also includes suitable cooling lines fluidly coupling heat transfer chamber 320, cooling pump 630, first radiator element 641 and second radiator element 642. For clarity, these cooling lines are omitted in FIG. 6B.

In the embodiment illustrated in FIGS. 6A and 6B, one cooling fan 603 directs cooling air 605 across first radiator element 641 and another cooling fan 603 directs cooling air 606 across second radiator element 642. In addition, in some embodiments, one cooling fan 603 directs cooling air 605 in a first direction 611 (shown in FIG. 6A) out of housing 601 and another cooling fan directs cooling air 606 in a second direction 612 (shown in FIG. 6B) out of housing 601. For example, in the embodiment illustrated in FIGS. 6A and 6B, cooling air 605 exits housing 601 via auxiliary cooling vanes 650 disposed on one or more sides of housing 601, while cooling air 606 exits housing 601 via air outlet 660. Alternatively, in other embodiments, the cooling fan 603 that directs cooling air 606 across second radiator element 642 operates as a pull/exhaust fan, and cooling air 606 flows in the opposite direction than that shown in FIGS. 6A and 6B. In such embodiments, air outlet 660 operates as an air inlet and air inlet 672 operates as an air outlet.

In some embodiments, one cooling fan 603 has an air inlet 671 on a first side of housing 601 and another cooling fan 603 has an air inlet 672 on another side of housing 601. For example, in the embodiment illustrated in FIGS. 6A and 6B, air inlet 671 is formed on a first side 681 of housing 601 and air inlet 672 is formed on a second side 682 of housing 601. In some embodiments, first side 681 is an opposite side of housing 601 from second side 682. In alternative embodiments, air inlet 671 and air inlet 672 can be disposed on a same side of housing 601.

In the embodiment illustrated in FIGS. 6A and 6B, card-based processing subsystem 600 includes two cooling fans 603 and two radiator elements (first radiator element 641 and second radiator element 642). In other embodiments, card-based processing subsystem 600 includes three or more cooling fans 603 and/or three or more radiator elements.

In the embodiment illustrated in FIGS. 6A and 6B, heat transfer chamber 320 is mounted on or coupled to IC package 310 and cooling pump 330 is mounted on or coupled to heat transfer chamber 320. In other embodiments, cooling pump 330 may be located elsewhere within housing 601.

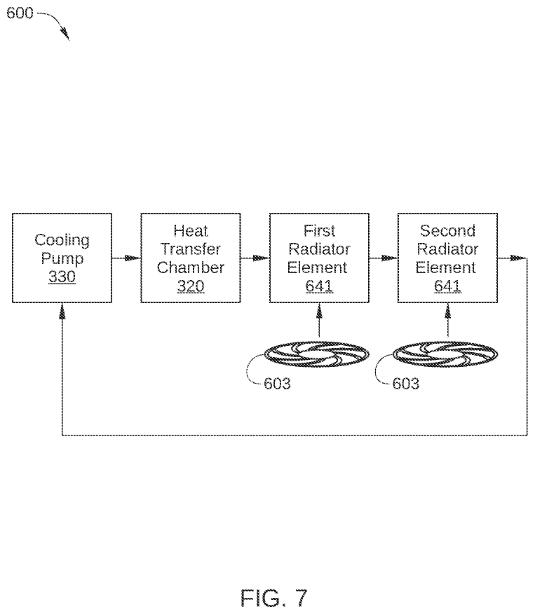

In some embodiments, the liquid cooling system of card-based processing subsystem 600 directs cooling liquid through first radiator element 641 and second radiator element 642 in series. Thus, in such embodiments, first radiator element 641 and one cooling fan 603 act as a first stage of cooling and second radiator element 642 and another cooling fan 603 act as a second stage of cooling. One such embodiment is described below in conjunction with FIG. 7. FIG. 7 is a conceptual block diagram of card-based processing subsystem 600, according to various embodiments. As shown, cooling liquid 701 flows from cooling pump 330 to heat transfer chamber 320, then in series through first radiator element 641 and second radiator element 642. In such embodiments, first radiator element 641 receives cooling liquid flow from the pump and second radiator element 642 receives the cooling liquid flow from first radiator element 641.

It is noted that, due to the high heat capacity and flow rate of cooling liquid flowing through first radiator element 641 and second radiator element 642, in many instances the cooling capacity of a single stage of the liquid-based cooling system included in card-based processing subsystem 600 can sufficiently cool IC package 310. Thus, in some embodiments, when one stage of the liquid-based cooling system can meet the current cooling requirements, the cooling fan for the other stage can operate a a lower fan speed, thereby significantly lowering the fan noise generated by card-based processing subsystem 600. Alternatively or additionally, in some embodiments, due to the cooling capacity of the liquid-based cooling system included in card-based processing subsystem 600, both cooling fans can operate at a lower fan speed, thereby significantly lowering the fan noise generated by card-based processing subsystem 600.

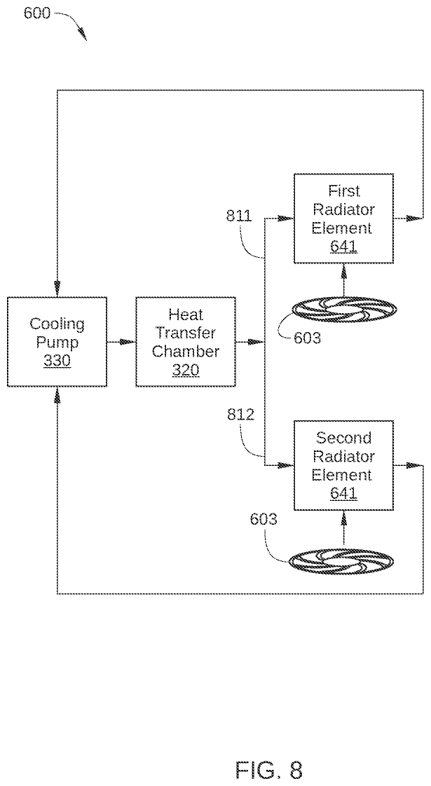

In some embodiments, the liquid cooling system of card-based processing subsystem 600 directs cooling liquid through first radiator element 641 and second radiator element 642 in parallel. One such embodiment is described below in conjunction with FIG. 8. FIG. 8 is a conceptual block diagram of card-based processing subsystem 600, according to various embodiments. As shown, cooling liquid 801 flows from cooling pump 330 to heat transfer chamber 320. After exiting heat transfer chamber 320, cooling liquid 801 is routed in parallel through first radiator element 641 and second radiator element 642. In such embodiments, first radiator element 641 receives a first portion 811 of cooling liquid flow from cooling pump 330 (e.g., via heat transfer chamber 320) while the second radiator element receives a remainder portion 812 of cooling liquid flow from the pump (e.g., via heat transfer chamber 320).

In sum, the various embodiments shown and provided herein set forth techniques for cooling high-power components in card-based processing subsystems, such as graphics cards. In the embodiments, a liquid cooling system is integrated into a card-based processing subsystem. Thus, the card-based processing subsystem includes a cooling pump, one or more radiator elements, one or more cooling fans, and a heat transfer chamber. As a result, when installed in a computer chassis, the card-based processing system does not rely on liquid cooling system components or systems that are located elsewhere within the computer chassis, such as a remote radiator, cooling pump, or supply of cooling liquid.

At least one technical advantage of the disclosed design relative to the prior art is that the disclosed design provides the heat-removing capacity of conventional liquid-based cooling systems to a card-based processing subsystem. With the disclosed design, the card-based processing system has the same form-factor as a conventional card-based processing subsystem that only includes a fan-based or multi-phase thermal solution. Thus, the disclosed design enables a card-based processing subsystem to have high cooling capacity and simple installation. A further advantage is that, due to the high cooling capacity of the liquid-based cooling system integrated into the card-based processing subsystem, lower fan speeds can be employed in many instances, significantly lowering the fan noise generated by the card-based processing subsystem. These technical advantages provide one or more technological advancements over prior art approaches.

1. In some embodiments, a processing subsystem includes: a housing; a printed circuit board (PCB) disposed within the housing; an integrated circuit package that has a first side and a second side that is opposite to the first side, wherein the first side of the integrated circuit package is mounted on the PCB; and a liquid-based cooling system that is disposed within the housing. The liquid-based cooling system includes: at least one radiator element; a pump that is fluidly coupled to the radiator element; and at least one fan that directs cooling air across the radiator element.

2. The processing subsystem of clause 1, wherein a portion of the heat transfer chamber coupled to the second side of the integrated circuit package includes a cold plate.

3. The processing subsystem of clauses 1 or 2, wherein the at least one radiator element includes a first radiator element and a second radiator element.

4. The processing subsystem of any of clauses 1-3, wherein the at least one fan includes a first fan that directs cooling air across the first radiator element and a second fan that directs cooling air across the second radiator element.

5. The processing subsystem of any of clauses 1-4, wherein the first radiator element receives a first portion of cooling liquid flow from the pump, while the second radiator element receives a remainder portion of the cooling liquid flow from the pump.

6. The processing subsystem of any of clauses 1-5, wherein the first radiator element receives a flow of cooling liquid from the pump, and the second radiator element receives the flow of cooling liquid from the first radiator element.

7. The processing subsystem of any of clauses 1-6, wherein the at least one fan includes a first fan that directs cooling air in a first direction away from the housing and a second fan that directs cooling air in a second direction away from the housing.

8. The processing subsystem of any of clauses 1-7, wherein the at least one fan includes a first fan that has a first air inlet on a first side of the housing and a second fan that has a second air inlet on a second side of the housing.

9. The processing subsystem of any of clauses 1-8, wherein the at least one radiator element includes a first radiator element and a second radiator element, and the at least one fan includes a first fan that directs cooling air across the first radiator element and a second fan that directs cooling air across the second radiator element.

10. The processing subsystem of any of clauses 1-9, wherein the liquid-based cooling system further includes a heat transfer chamber that is coupled to the second radiator element.

11. The processing subsystem of any of clauses 1-10, wherein the pump is mounted on the heat transfer chamber.

12. The processing subsystem of any of clauses 1-11, wherein the PCB includes a plurality of electrical connectors to connect the processing subsystem to a computer motherboard via a card edge connector.

13. The processing subsystem of any of clauses 1-12, wherein the PCB includes one or more mechanical connection features to connect the processing subsystem to a computer motherboard via a card edge connector.

14. The processing subsystem of any of clauses 1-13, wherein the liquid-based cooling system further includes a heat transfer chamber that is coupled to the second side of the integrated circuit package and is fluidly coupled to the radiator element.

15. In some embodiments, a computer system includes: a chassis; a motherboard that is disposed within the chassis and is electrically coupled to a power supply; and a processing subsystem that is disposed within the chassis and is coupled to the motherboard. The processing subsystem includes: a housing; a printed circuit board (PCB) disposed within the housing; an integrated circuit package that has a first side and a second side that is opposite to the first side, wherein the first side of the integrated circuit package is mounted on the PCB; and a liquid-based cooling system that is disposed within the housing. The liquid-based cooling system includes: at least one radiator element; a pump that is fluidly coupled to the radiator element; and at least one fan that directs cooling air across the radiator element.

16. The computer system of clause 15, wherein the housing has a form factor that occupies a region corresponding to an integral number of expansion slots on a computer motherboard.

17. The computer system of clauses 15 or 16, wherein the liquid-based cooling system further includes a heat transfer chamber that is coupled to the second side of the integrated circuit package and is fluidly coupled to the radiator element.

18. The computer system of any of clauses 15-17, wherein the PCB includes a plurality of electrical connectors to connect the processing subsystem to a computer motherboard via a card edge connector.

19. The computer system of any of clauses 15-18, wherein the PCB includes one or more mechanical connection features to connect the processing subsystem to a computer motherboard via a card edge connector.

20. The computer system of any of clauses 15-19, wherein the pump is mounted on the heat transfer chamber.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. A processing subsystem, comprising:
a housing;
a printed circuit board (PCB) disposed within the housing;
an integrated circuit package that has a first side and a second side that is opposite to the first side, wherein the first side of the integrated circuit package is mounted on the PCB; and
a liquid-based cooling system that is disposed within the housing and includes:
at least one radiator element;
a pump that is fluidly coupled to the radiator element; and
at least one fan that directs cooling air across the radiator element.

2. The processing subsystem of claim 1, wherein a portion of the heat transfer chamber coupled to the second side of the integrated circuit package includes a cold plate.

3. The processing subsystem of claim 1, wherein the at least one radiator element includes a first radiator element and a second radiator element.

4. The processing subsystem of claim 2, wherein the at least one fan includes a first fan that directs cooling air across the first radiator element and a second fan that directs cooling air across the second radiator element.

5. The processing subsystem of claim 2, wherein the first radiator element receives a first portion of cooling liquid flow from the pump, while the second radiator element receives a remainder portion of the cooling liquid flow from the pump.

6. The processing subsystem of claim 2, wherein the first radiator element receives a flow of cooling liquid from the pump, and the second radiator element receives the flow of cooling liquid from the first radiator element.

7. The processing subsystem of claim 2, wherein the at least one fan includes a first fan that directs cooling air in a first direction away from the housing and a second fan that directs cooling air in a second direction away from the housing.

8. The processing subsystem of claim 2, wherein the at least one fan includes a first fan that has a first air inlet on a first side of the housing and a second fan that has a second air inlet on a second side of the housing.

9. The processing subsystem of claim 1, wherein the at least one radiator element includes a first radiator element and a second radiator element, and the at least one fan includes a first fan that directs cooling air across the first radiator element and a second fan that directs cooling air across the second radiator element.

10. The processing subsystem of claim 9, wherein the liquid-based cooling system further includes a heat transfer chamber that is coupled to the second radiator element.

11. The processing subsystem of claim 1, wherein the pump is mounted on the heat transfer chamber.

12. The processing subsystem of claim 1, wherein the PCB includes a plurality of electrical connectors to connect the processing subsystem to a computer motherboard via a card edge connector.

13. The processing subsystem of claim 1, wherein the PCB includes one or more mechanical connection features to connect the processing subsystem to a computer motherboard via a card edge connector.

14. The processing subsystem of claim 1, wherein the liquid-based cooling system further includes a heat transfer chamber that is coupled to the second side of the integrated circuit package and is fluidly coupled to the radiator element.

15. A computer system, comprising:
a chassis;
a motherboard that is disposed within the chassis and is electrically coupled to a power supply; and
a processing subsystem that is disposed within the chassis and is coupled to the motherboard, the processing subsystem including:
a housing;
a printed circuit board (PCB) disposed within the housing;
an integrated circuit package that has a first side and a second side that is opposite to the first side, wherein the first side of the integrated circuit package is mounted on the PCB; and
a liquid-based cooling system that is disposed within the housing and includes:
at least one radiator element;
a pump that is fluidly coupled to the radiator element; and
at least one fan that directs cooling air across the radiator element.

16. The computer system of claim 15, wherein the housing has a form factor that occupies a region corresponding to an integral number of expansion slots on a computer motherboard.

17. The computer system of claim 15, wherein the liquid-based cooling system further includes a heat transfer chamber that is coupled to the second side of the integrated circuit package and is fluidly coupled to the radiator element.

18. The computer system of claim 15, wherein the PCB includes a plurality of electrical connectors to connect the processing subsystem to a computer motherboard via a card edge connector.

19. The computer system of claim 15, wherein the PCB includes one or more mechanical connection features to connect the processing subsystem to a computer motherboard via a card edge connector.

20. The computer system of claim 15, wherein the pump is mounted on the heat transfer chamber.
